(19) United States
(12) Patent Application Publication
(10) Pub. No.: US 2006/0086890 A1
(43) Pub. Date: Apr. 27, 2006

(54) Package structure of image sensor device

(75) Inventors: Yeong-Ching Chao, Tainan (TW); An-Hong Liu, Tainan (TW); Yao-Jung Lee, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS TECHNOLOGIES (Bermuda) LTD.; ChipMOS TECHNOLOGIES INC.

(21) Appl. No.: 11/254,660

(22) Filed: Oct. 21, 2005

(30) Foreign Application Priority Data
Oct. 21, 2004 (TW) 093216783

(51) Int. Cl. H01L 27/00

(52) U.S. Cl. 250/208.1

(57) ABSTRACT

An image sensor package mainly includes a substrate cover having a chip cavity, an image sensor chip, a flexible circuit, and a transparent carrier. The flexible circuit is attached to the transparent carrier. The image sensor chip is flip-chip mounted on the flexible circuit, and then the substrate cover is mounted on the flexible circuit. The flexible circuit has a plurality of first leads electrically connected to bumps of the image sensor chip, and a plurality of second leads to inner terminals of the substrate cover, so that the electrical connection is established between the image sensor chip and the substrate cover through the flexible circuit. A plurality of outer terminals are formed on the opposing surface of the substrate cover corresponding to the inner terminals. Accordingly, the image sensor package provides the excellent electrical transmission and the protection of the image sensor chip. Preferably, a liquid sealant, NCP, or ACP is disposed between the substrate cover and the flexible circuit for hermetically sealing the image sensor chip in the chip cavity. In another embodiment, a glass substrate can replace the assembly of the flexible circuit and the transparent carrier.

### FIELD OF THE INVENTION

The present invention relates to an image sensor package, and more particularly, to an image sensor package using a substrate cover having a chip cavity to accommodate a COF or COG type image sensor chip and to prevent the image sensor chip from damage and contamination of a liquid sealant.

### BACKGROUND OF THE INVENTION

Image sensor devices have been widely implemented in everyday lives such as cellular phones, personal digital assistants (PDA), digital still cameras (DSC), digital video cameras (DV), video phones, video conferences, and so on. As shown in FIG. 1, a conventional image sensor package comprises a substrate 11, a stiffener 12, an image sensor chip 13, a plurality of bonding wires 14, and a glass cover 15. The stiffener 12 is adhered to the substrate 11 to form a chip cavity. The image sensor chip 13 is attached to the upper surface of the substrate 11 in the chip cavity. The image sensor chip 13 is electrically connected to the substrate 11 by a plurality of bonding wires 14. The glass cover 15 is adhered to the stiffener 12 to hermetically seal the image sensor chip 13. Normally the chip cavity is much larger than the image sensor chip 13 because of the loop height and length of the bonding wires 14. Therefore, the thickness of an image sensor package cannot efficiently be reduced.

Furthermore, another known image sensor package is disclosed in R.O.C. Taiwan patent publication No. 542493, entitled “Image sensor structure”. The package comprises a substrate, a protrusion layer, an image sensor chip, and a light-transmission layer (glass cover). The image sensor chip is disposed in the chip cavity formed by the substrate and the protrusion layer. A plurality of signal input terminals are formed on the upper surface of the protrusion layer to provide electrical connections to the image sensor chip by a plurality of bonding wires. Then, through the circuit on the sidewalls of the protrusion layer and the sidewalls of the substrate, the electrical signals are transmitted to the substrate. An adhesive is partially disposed on the upper surface of the protrusion layer to adhere the light-transmission layer. However, during the packaging processes, the protrusion layer has to be formed on top of the substrate to form the chip cavity, which is very complicated. The depth of the chip cavity is much larger than the thickness of the image sensor chip, and the loop height of the bonding wires are always higher than the upper surface of the protrusion layer. When the light-transmission layer is attached to the protrusion layer, the bonding wires will be damaged resulting in electrical short or open.

### SUMMARY OF THE INVENTION

The main purpose of the present invention is to provide an image sensor package in which an image sensor chip is flip-chip mounted on a flexible circuit on a transparent carrier or a glass substrate, and a substrate cover is mounted on the flexible circuit/glass substrate. The substrate cover has a chip cavity and a plurality of electrical terminals. When disposition of the substrate cover, the chip cavity will accommodate the image sensor chip and the terminals of the substrate cover are electrically connected to the image sensor chip by the flexible circuit/glass substrate to replace the conventional bonding wires in the chip cavity. The image sensor package can meet the development of miniaturization with excellent protection of the image sensor chip.

The secondary purpose of the present invention is to provide an image sensor package in which an annular gap is formed between the substrate cover and the image sensor chip to prevent a liquid sealant from wetting the image sensor chip. The liquid sealant such as underfill material is formed between the substrate cover and the flexible circuit/glass substrate, can be used for hermetically sealing the image sensor chip without contaminating a sensing area of the image sensor chip.

The third purpose of the present invention is to provide an image sensor package in which the spacing between the substrate cover and the flexible circuit/glass substrate is smaller than that between the image sensor chip and the flexible circuit/glass substrate. The liquid sealant is formed between the substrate cover and the flexible circuit/glass substrate, can be used for hermetically sealing the image sensor chip without contaminating the image sensor chip.

According to the present invention, an image sensor package mainly includes a transparent carrier having a flexible circuit or including a glass substrate, an image sensor chip, and a substrate cover. The flexible circuit has a plurality of traces, a plurality of first leads and a plurality of second leads. The image sensor chip is flip-chip mounted on the flexible circuit, wherein a plurality of bumps are formed on the active surface of the image sensor chip and bonded to the first leads. The substrate cover is also mounted on the flexible circuit, the substrate cover has a first surface, a second surface, and a chip cavity in the first surface. Therein a plurality of inner terminals are formed on the first surface, and a plurality of outer terminals are formed on the second surface and electrically connected to the corresponding inner terminals.

### DESCRIPTION OF THE DRAWINGS

FIG. 1 is a cross-sectional view of a known image sensor package.

FIG. 2 is a cross-sectional view of an image sensor package according to the first embodiment of the present invention.

FIG. 3 is a cross-sectional view of the image sensor package during mounting a substrate cover according to the first embodiment of the present invention.

FIG. 4 is a cross-sectional view of another image sensor package according to the second embodiment of the present invention.

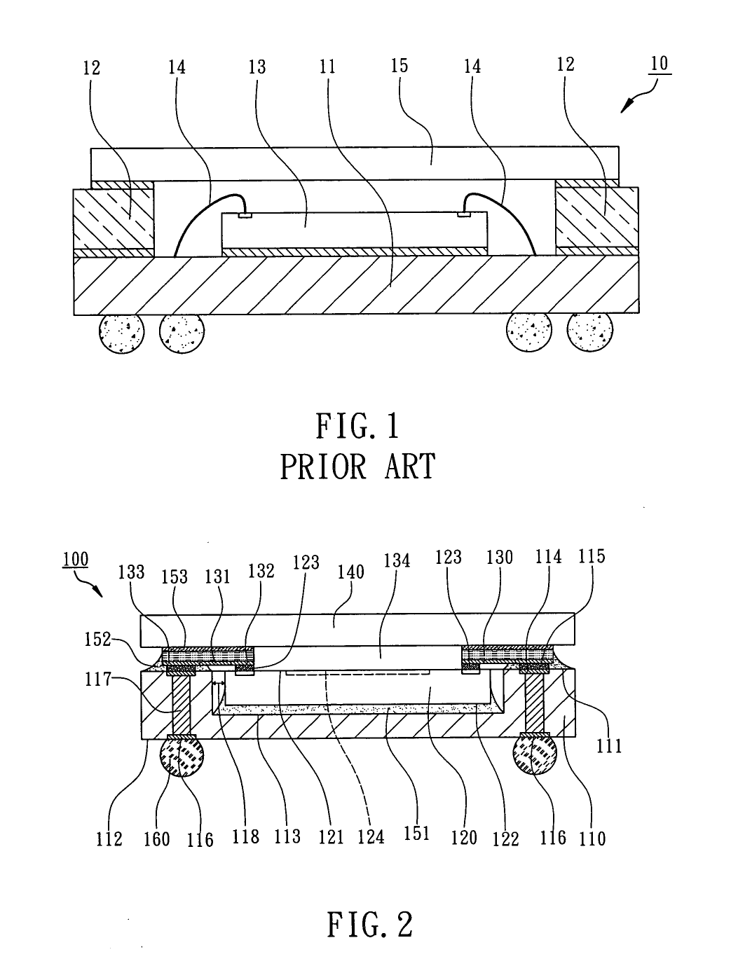

### DETAIL DESCRIPTION OF THE INVENTION

Please refer to the attached drawings, the present invention will be described by means of embodiment(s) below.

FIG. 2 shows an image sensor package 100 according to the first embodiment of the present invention, the package 100 comprises a substrate cover 110, an image sensor chip 120, a flexible circuit 130, and a transparent carrier 140. The transparent carrier 140 is rigid for attaching the flexible circuit 130 and flip-chip mounting. Preferably, the transparent carrier 140 is an optical glass.

The flexible circuit 130 is attached to the transparent carrier 140 by adhesive 153. The flexible circuit 130 may be selected from a COF (Chip-On-Film) tape, a TCP (Tape Automated Package) tape, or a high-density FPC. The flexible circuit 130 has a plurality of traces 131, a plurality of first leads 132, and a plurality of second leads 133. Therein the materials of the traces 131 may be chosen from copper, aluminum, or nickel, such as 0.07 mm of copper foil. In this embodiment, the flexible circuit 130 has an opening 134 which is aligned with a sensing area 124 of the image sensor chip 120. The trace 131 connect the corresponding first leads 132 and the corresponding second leads 133, wherein the first leads 132 are used for electrical connection of a plurality of bumps 123 of the image sensor chip 120.

The image sensor chip 120 is flip-chip mounted on the flexible circuit 130. The image sensor chip 120 may be a charged coupled device (CCD), or a CMOS image sensor chip enables to convert the received light signals into digital electrical signals. The image sensor chip 120 has an active surface 121 and a back surface 122, and also is a bumped chip, where a plurality of bumps 123 are formed on the peripheries of the active surface 121, such as solder bumps, gold bumps, or conductive polymer bumps. Using ultrasonic bonding, reflowing, thermal compression bonding, ACP, ACF connection, or NCP connection, the flip-chip mounting can be accomplished. Therein ultrasonic bonding is preferable to mount the image sensor chip 120 under low temperature (about 150°). Accordingly, the bumps 123 are bonded to the first leads 132.

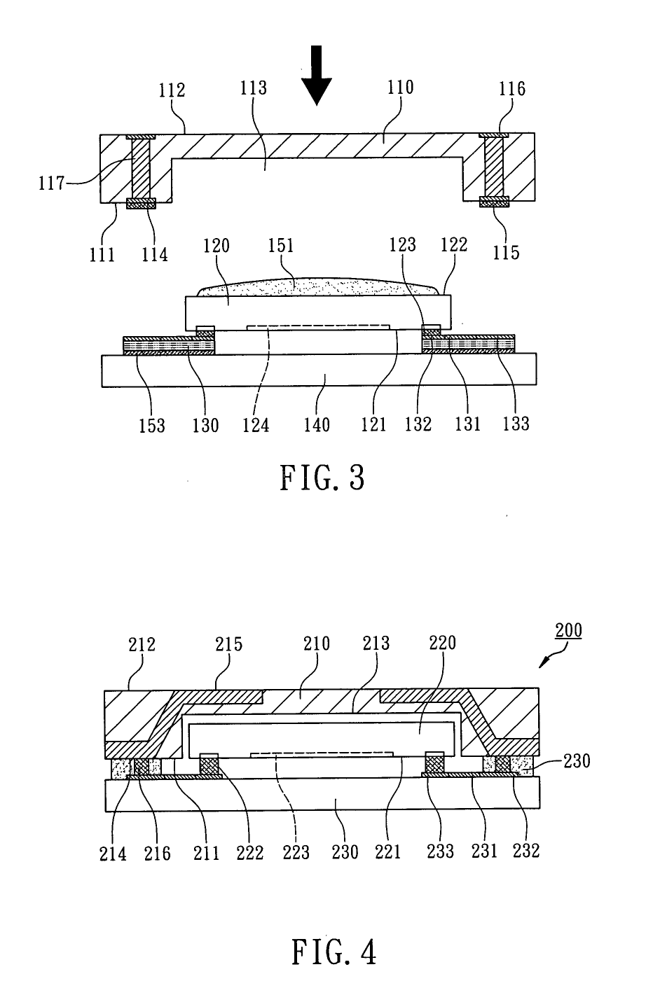

As shown in FIG. 3, the substrate cover 110 is also mounted on the flexible circuit 130 by SMT. The substrate cover 110 may be selected from ceramic, BT, FR-4, or FR-5 wiring substrate. The substrate cover 110 has a first surface 111, a second surface 112, and a chip cavity 113 in the first surface 111 for accommodating the image sensor chip 120 to replace the conventional molding compound. The depth of the chip cavity 113 can be smaller to match the dimensions of the image sensor chip 120. The substrate cover 110 includes a plurality of inner terminals 114 and a plurality of outer terminals 116 where the inner terminals 114 are formed on the first surface 111 around the chip cavity 113, the outer terminals 116 are formed on the second surface 112 and electrically connected to the corresponding inner terminals 114 by internal wiring structure of the substrate cover 110, for example a plurality of plated through holes (PTH) 117. When SMT mounting of the substrate cover 110, a plurality of solder bumps 115 formed on the inner terminals 114 can bond to the second leads 133 of the flexible circuit 130. Accordingly, the image sensor chip 120 is electrically connected to the outer terminal 116 by the flexible circuit 130 and the substrate cover 110. Preferably, a plurality of solder balls 160 are placed on the outer terminals 116 so that the converted electrical signals of the image sensor chip 120 can be transmitted to an external printed circuit board (not shown in the drawing).

Preferably, a thermal interface material (TIM) 151 or other thermal grease is located between the back surface 122 of the image sensor chip 120 and the chip cavity of the substrate cover 110 to improve thermal dissipation of the image sensor chip 120.

Furthermore, a liquid sealant 152 is disposed between the substrate cover 110 and the flexible circuit 130 to hermetically sealing the image sensor chip 120 in the chip cavity 113. The liquid sealant 152 is a thermosetting resin with high fluidity prior to curing, such as underfill material. Referring to FIG. 2 again, an annular gap 118 is formed between the first surface 111 of the substrate cover 110 and the active surface 121 of the image sensor chip 120. The liquid sealant 152 during dispensing will be limited to prevent from wetting the image sensor chip 120. After curing, the liquid sealant 152 may encapsulate the solder bumps 115.

FIG. 4 shows another image sensor package 200 according to the second embodiment of the present invention, almost as the same as the first embodiment except for the transparent carrier. The package 200 comprises a substrate cover 210, an image sensor chip 220, and a transparent carrier including a glass substrate 230. The glass substrate 230 has a plurality of traces 231, a plurality of first leads 232 and a plurality of second leads 233 where the traces 231 may be made of ITO (Indium Tin Oxide). The image sensor chip 220 is flip-chip mounted on the glass substrate 230 where a plurality of bumps 222 are formed on the active surface 221 of the image sensor chip 220 and bonded to the first leads 232. The substrate cover 210 is mounted on the glass substrate 230. In addition, the substrate cover 210 has a first surface 211, a second surface 212, and a chip cavity 213 in the first surface 211. In this embodiment, the substrate cover 210 is a leadframe-based pre-molded body, wherein a plurality of inner terminals 214 are formed on the first surface 211, and a plurality of outer terminals 215 are formed on the second surface 212 and electrically connected to the corresponding inner terminals 214 by leads of an leadframe. The inner terminals 214 includes a plurality of bumps 216 such as stud bumps or BCC plated bumps, on the first surface 211. NCP (non-conductive paste) 240 or ACP (antisotropic conductive paste) is disposed on the glass substrate 230 to cover the outer leads 233. After mounting the substrate cover 210, the inner terminals 214 are electrically connected with the outer leads 233 by the bumps 216, and the NCP/ACP 240 between the substrate cover 210 and the glass substrate 230 for hermetically sealing the image sensor chip 220 in the chip cavity 213. Preferably, the spacing between the substrate cover 210 and the glass substrate 230 is smaller than that between the image sensor chip 220 and the glass substrate 230 so that the NCP/ACP 240 will not contaminate the image sensor chip 220.

The above description of embodiments of this invention is intended to be illustrative and not limiting. Other embodiments of this invention will be obvious to those skilled in the art in view of the above disclosure.

What is claimed is:

1. An image sensor package comprising:
a transparent carrier;
a flexible circuit attached to the transparent carrier, wherein the flexible circuit has a plurality of traces, a plurality of first leads and a plurality of second leads;
an image sensor chip mounted on the flexible circuit, the image sensor chip having an active surface and a back surface, wherein a plurality of bumps are formed on the active surface and bonded to the first leads; and
a substrate cover mounted on the flexible circuit, the substrate cover having a first surface, a second surface, and a chip cavity in the first surface, wherein a plurality of inner terminals are formed on the first surface, and a plurality of outer terminals are formed on the second surface and electrically connected to the corresponding inner terminals.

2. The image sensor package of claim 1, further comprising a liquid sealant disposed between the substrate cover and the flexible circuit for hermetically sealing the image sensor chip.

3. The image sensor package of claim 2, wherein an annular gap is formed between the first surface of the substrate cover and the active surface of the image sensor chip to prevent the liquid sealant from wetting the image sensor chip.

4. The image sensor package of claim 1, further comprising an NCP (non-conductive paste) or ACP (antisotropic conductive paste) formed between the substrate cover and the flexible circuit for hermetically sealing the image sensor chip.

5. The image sensor package of claim 1, wherein the spacing between the substrate cover and the flexible circuit is smaller than that between the image sensor chip and the flexible circuit.

6. The image sensor package of claim 1, wherein the flexible circuit has an opening aligned with a sensing area of the image sensor chip.

7. The image sensor package of claim 1, further comprising a thermal interface material located between the back surface of the image sensor chip and the chip cavity of the substrate cover.

8. The image sensor package of claim 1, further comprising a plurality of solder bumps on the inner terminals.

9. The image sensor package of claim 1, wherein the transparent carrier is an optical glass.

10. The image sensor package of claim 1, further comprising a plurality of solder balls on the outer terminals.

11. An image sensor package comprising:
a carrier including a glass substrate, wherein the glass substrate has a plurality of traces, a plurality of first leads and a plurality of second leads;
an image sensor chip mounted on the glass substrate, the image sensor chip having an active surface and a back surface, wherein a plurality of bumps are formed on the active surface and bonded to the first leads; and
a substrate cover mounted on the glass substrate, the substrate cover having a first surface, a second surface, and a chip cavity in the first surface, wherein a plurality of inner terminals are formed on the first surface, and a plurality of outer terminals are formed on the second surface and electrically connected to the corresponding inner terminals.

12. The image sensor package of claim 11, further comprising a liquid sealant disposed between the substrate cover and the glass substrate for hermetically sealing the image sensor chip.

13. The image sensor package of claim 12, wherein an annular gap is formed between the first surface of the substrate cover and the active surface of the image sensor chip to prevent the liquid sealant from wetting the image sensor chip.

14. The image sensor package of claim 11, further comprising an NCP (non-conductive paste) or ACP (antisotropic conductive paste) formed between the substrate cover and the glass substrate for hermetically sealing the image sensor chip.

15. The image sensor package of claim 11, wherein the spacing between the substrate cover and the glass substrate is smaller than that between the image sensor chip and the glass substrate.

16. The image sensor package of claim 11, further comprising a thermal interface material located between the back surface of the image sensor chip and the chip cavity of the substrate cover.

17. The image sensor package of claim 11, further comprising a plurality of solder bumps on the inner terminals.

18. The image sensor package of claim 11, further comprising a plurality of solder balls on the outer terminals.
